(19) United States
(12) Patent Application Publication
(10) Pub. No.: US 2026/0305172 A1
(43) Pub. Date: Oct. 1, 2026

(54) METHOD FOR PREPARING A THIN LAYER OF FERROELECTRIC MATERIAL

(71) Applicant: Soitec, BERNIN (FR)

(72) Inventors: Edouard de Moustier, BERNIN (FR); Alexis Drouin, BERNIN (FR); Rénald Guerin, BERNIN (FR)

(21) Appl. No.: 19/474,898

(22) PCT Filed: Apr. 8, 2024
(86) PCT No.: PCT/EP2024/059520

§ 371 Date: Oct. 13, 2025

(30) Foreign Application Priority Data
Apr. 26, 2023 (FR) FR2304220

(51) Int. Cl. H10N 30/07; H10P 10/00; H10P 70/00; H10P 95/90

(52) U.S. Cl. CPC H10N 30/07; H10P 10/12; H10P 70/20; H10P 95/90

(57) ABSTRACT

A method of preparing a thin single-domain layer of ferroelectric material includes, between a step of fracturing a donor substrate at a weakened plane to form a first layer and a finishing sequence for finishing the first layer, applying a treatment to the free face of the first layer to produce a hydrogen concentration that is greater than 2.0E21 at/cm³ in a surface thickness of the first layer.

### CROSS-REFERENCE TO RELATED APPLICATIONS

This application is a national phase entry under 35 U.S.C. § 371 of International Patent Application PCT/EP2024/059520, filed Apr. 8, 2024, designating the United States of America and published as International Patent Publication WO 2024/223276 A1 on Oct. 31, 2024, which claims the benefit under Article 8 of the Patent Cooperation Treaty of French Patent Application Serial No. FR2304220, filed Apr. 26, 2023.

### TECHNICAL FIELD

The present disclosure relates to a method for preparing a thin layer of ferroelectric material. More specifically, the present disclosure relates to a preparation method that allows the single-domain character of the ferroelectric material to be maintained in the thin layer of the final product. This preparation method is used, for example, in the fields of microelectronics, micromechanics, photonics, etc.

### BACKGROUND

By way of an introduction and reminder, a ferroelectric material is a material with electrical polarization in the natural state, with this polarization being able to be reversed by applying an external electric field. The ferroelectric domain refers to each continuous region of the material in which the polarization is uniform (all the dipole moments are aligned parallel to each other in a given direction). A ferroelectric material therefore can be characterized as “single-domain” in the event that this material is made up of a single region in which the polarization is uniform or can be characterized as “multi-domain” in the event that the ferroelectric material comprises a plurality of regions having polarities that may be different.

The present disclosure more specifically relates to the preparation of a thin ferroelectric layer obtained by applying Smart Cut™ technology, according to which a thin layer is removed from a solid substrate of ferroelectric material by fracturing in the vicinity of a weak zone (or weakened plane) formed in the solid substrate by implanting “light” species, such as helium or hydrogen. A specific example of the implementation of this method can be found in European Patent No. EP 3646374 B1.

According to this method, and after the step of removing the layer, it is often necessary to apply treatments thereto in order improve its surface finish, its crystalline quality or to modify its thickness. However, it has been observed that these preparation steps, when they were applied to a thin ferroelectric layer attached to a silicon support, can lead to the formation of a plurality of ferroelectric domains within the thin layer, thus attributing a multi-domain character thereto.

Such a characteristic makes the layer unsuitable for use, as it affects the performance capabilities of devices that are to be formed on/in the thin layer, such as surface acoustic wave (SAW) devices, for example.

International Patent Application Publication No. WO 2020/200986 discloses that the formation of ferroelectric domains in a surface portion of the layer is caused by the existence of hydrogen concentration gradients in the thin layer when applying a heat treatment. This hydrogen can notably correspond to the light species implanted in the solid substrate in order to form the weakened zone therein from which the thin layer can be removed. The thickness of the surface portion can be on the order of 150 nm to 200 nm or more. In order to permanently restore the single-domain character of the thin layer, this document recommends thinning the thin ferroelectric layer after applying such a heat treatment.

This thinning notably can be carried out by chemical-mechanical polishing of the layer, but removing a relatively large thickness of materials by polishing tends to deteriorate the thickness uniformity of this layer. By way of an example, removing a thickness on the order of 400 nm leads to the formation of a layer with a thickness uniformity (i.e., the difference between the largest thickness and the lowest thickness when this thickness measurement is carried out, for example, by reflectometry or ellipsometry, at multiple measurement points over the entire extent of the layer) that is on the order of 100 nm. This variability in thickness is not acceptable, as it does not allow devices with all the required characteristics to be collectively manufactured from such a layer.

There are alternatives to thinning using chemical-mechanical polishing. Notably, thinning the thin ferroelectric film by ion etching can be contemplated, for example, by Reactive Ion Etching (RIE). RIE is a type of dry etching that uses a plasma of chemically reactive ions to remove the surface material from a wafer. The plasma is generated under low pressure by an electromagnetic field. The high-energy ions of the plasma attack the surface of the layer and react therewith in order to pulverize it, and thus gradually thin the layer. Such an approach is notably described in French Patent Application No. FR 2111960.

However, and irrespective of whether it is carried out by chemical-mechanical polishing or by ion etching, removing a relatively large thickness of material in order to remove the multi-domain surface portion of the removed layer is a disadvantage of the methods of the prior art, as this step tends to make the manufacturing method longer and more complex to implement.

This elimination step also requires the removal of a layer with a relatively large thickness from the solid substrate of ferroelectric material, which requires the light species to be implanted with a significant amount of energy. Beyond a certain threshold thickness, the energy required to define the removed layer is beyond the reach of existing implantation equipment. A method for preparing a thin single-domain layer of ferroelectric material of the prior art therefore has limitations that would be beneficial to overcome.

### BRIEF SUMMARY

An aim of the present disclosure is to propose a method for preparing a thin layer of ferroelectric material that at least partly addresses some of the aforementioned limitations. More specifically, an aim of the present disclosure is to propose a method for preparing a thin layer of ferroelectric material that is simpler to implement than the methods of the prior art. Another aim of the present disclosure is to propose a method for thinning a thin layer obtained by detaching a donor substrate at a weakened plane, in which method the thickness of materials removed in order to remove the multi-domain surface portion of the removed layer is lower than the thickness removed in the methods of the prior art.

With a view to achieving one of these aims, the subject matter of the present disclosure proposes a method for preparing a thin single-domain layer of ferroelectric material, the method comprising:
a step of implanting “light” species in a first face of a ferroelectric donor substrate in order to form a weakened plane and to define a first layer between the weakened plane and the first face of the donor substrate;
a step of assembling the first face of the donor substrate on a support in order to form an intermediate assembly;
a step of fracturing the intermediate assembly, comprising a first heat treatment, with this step leading to the fracturing of the donor substrate at the weakened plane and to the formation of a free face of the first layer;
a sequence for finishing the first layer comprising an annealing step including a second heat treatment and, after the annealing step, a step of thinning the first layer in order to form the thin single-domain layer.

According to the present disclosure, the preparation method comprises, between the fracturing step and the finishing sequence, applying a treatment to the free face in order to produce a hydrogen concentration that is greater than 2.0E21 at/cm³ in a surface thickness of the first layer.

According to other advantageous and non-limiting features of the present disclosure, taken individually or according to any technically feasible combination:
the surface thickness, in which the hydrogen concentration is greater than 2.0E21 at/cm³, is greater than or equal to 100 nm;
the surface thickness is greater than or equal to 200 nm;
the treatment of the free face introduces a hydrogen dose into the first layer that is greater than or equal to 2.0E16 at/cm²;
the treatment of the free face comprises immersing the first layer in a first solution having a temperature higher than ambient temperature;
the first solution comprises SC1 and/or SC2;
the temperature of the first solution is greater than 50° C., preferably greater than 65° C.;
the treatment of the free face comprises a sequence of cleaning steps using a second solution, with the cleaning steps of the sequence being separated from one another by a waiting time of 24 hours or more;
the second solution comprises deionized water, the cleaning steps simultaneously comprising brushing and dispensing deionized water onto the free face of the first layer;
the second solution is at ambient temperature;
the sequence of cleaning steps comprises at least three cleaning steps, preferably at least five cleaning steps;
the treatment of the free face comprises depositing a covering layer onto the free face with a hydrogen concentration that is greater than 1.0E20 at/cm³;
the covering layer comprises silicon dioxide, silicon nitride or silicon oxynitride;
the covering layer is 20 nm or more thick;
the thin single-domain layer is made up of a single-crystal piezoelectric material, such as lithium tantalate or lithium niobate;
the thin single-domain layer is made up of lithium niobate;
the assembly step comprises forming a dielectric interlayer on the first face of the donor substrate and/or on the support.

### BRIEF DESCRIPTION OF THE DRAWINGS

Further features and advantages of the present disclosure will become apparent from the following detailed description of embodiments of the present disclosure, which is provided with reference to the appended figures, in which:

FIGS. 1A-IF show a step of preparing a thin layer according to a first embodiment;

FIGS. 2A-2F show a step of preparing a thin layer according to a second embodiment;

FIG. 3 is a graph of an analysis of a removed layer;

FIG. 4 shows a preparation method according to the present disclosure.

### DETAILED DESCRIPTION

The present disclosure relates to a method for preparing a thin single-domain layer 3′ of a ferroelectric material transferred from a single-crystal donor substrate 1 onto a support substrate 7 using a transfer technique including implanting light species in a donor substrate 1. Several embodiments exist for this step of providing a thin layer.

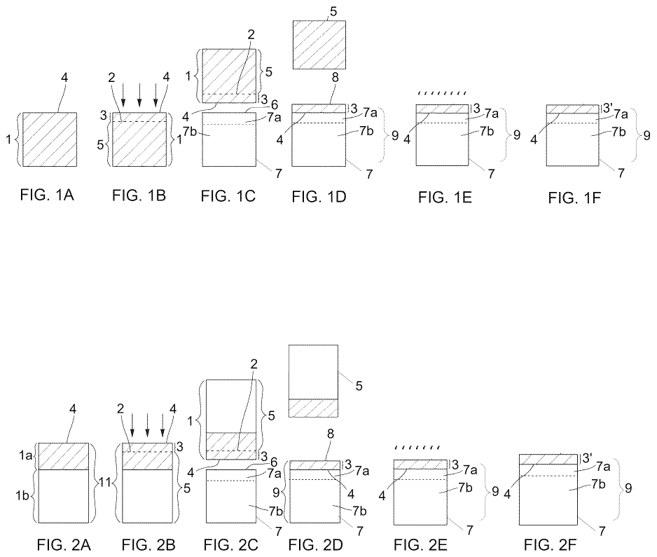

According to a first embodiment, shown in FIGS. 1A to 1F, the donor substrate 1 is made up of a solid, single-crystal and single-domain block of ferroelectric material, for example, LiTaO₃, LiNbO₃, LiAlO₃, BaTiO₃, PbZrTiO₃, KNbO₃, BaZrO₃, CaTiO₃, PbTiO₃ or KTaO₃. The donor substrate 1 can assume the form of a standardized size circular wafer, for example, with a diameter of 150 mm or 200 mm. However, the invention is by no means limited to these sizes or to this shape. The donor substrate may have been removed from an ingot of ferroelectric materials in such a way as to form the donor substrate 1 with a predetermined crystal orientation. The orientation is selected as a function of the intended application. Thus, an orientation ranging between 30° and 60° RY, or between 40° and 50° RY, is usually selected when the intention is to use the properties of a thin layer of LiTaO₃ to form an SAW filter. However, the invention is by no means limited to a particular crystal orientation.

Irrespective of the crystal orientation of the donor substrate 1, the method comprises introducing at least one “light” species into the donor substrate 1, notably species selected from inert gases or hydrogen. This introduction can correspond to an implantation, i.e., ion bombardment of a flat face 4 of the donor substrate 1 by light species such as hydrogen and/or helium ions.

In a manner known per se, and as shown in FIG. 1B, the implanted ions are intended to form a weakened plane 2 delimiting a first layer 3 of ferroelectric material to be transferred that is located on the side of the flat face 4, and another part 5 forming the rest of the substrate.

The type and dose of the implanted species and the implantation energy are selected as a function of the thickness of the layer to be transferred and of the physico-chemical properties of the donor substrate. In the case of a donor substrate 1 made of LiTaO₃, implanting a hydrogen dose ranging between 1E16 and 5E17 at/cm² with an energy level ranging between 30 and 300 keV thus can be selected in order to delimit a first layer 3 on the order of 200 to 2,000 nm.

In a subsequent step, shown in FIG. 1C, the flat face 4 of the donor substrate 1 is assembled with a face 6 of a support substrate 7. The support substrate 7 can assume the same size and shape as the donor substrate 1. For availability and cost reasons, the support substrate 7 is a monocrystalline or polycrystalline silicon wafer. However, more generally, the support substrate 7 can be made up of any material, for example, silicon, sapphire or glass, and can assume any shape.

In a particular embodiment, the support substrate comprises a base substrate 7b, for example, made of single-crystal silicon, on which a charge trapping layer 7a is arranged. The base substrate 7b can have high resistivity, greater than 1,000 ohms·cm or, more conventionally, less than 1,000 ohms·cm. The charge trapping layer 7a, as is well known per se, can be formed by a polycrystalline silicon layer, and typically can have a thickness ranging between 500 nm and 10 microns.

Prior to the assembly step, the faces of the substrates to be assembled may be prepared by a step of cleaning, brushing, drying, polishing or plasma activation, for example.

The assembly step can involve bringing the donor substrate 1 into close contact with the support substrate 7 by molecular adhesion and/or electrostatic bonding. Optionally, in order to facilitate the assembly of the two substrates 1, 7, notably when they are assembled by direct bonding, at least one amorphous interlayer can be formed prior to assembly, either on the flat face 4 of the donor substrate 1, or on the flat face 6 of the support substrate 7 to be assembled, or on both. This interlayer is made up of silicon oxide, silicon nitride or silicon oxynitride, for example. Its thickness can range between a few nanometers and a few microns.

An interlayer with a low concentration of hydrogen or forming a barrier to hydrogen diffusion is preferred in order to follow the teaching of document WO 2020/200986 and thus avoid the formation of a multi-domain zone at the interface between the first layer 3 and the amorphous interlayer, on the side of the second face of the first layer 3. The interlayer can be produced using various known techniques of the prior art, such as thermal oxidation or nitridation treatments, chemical deposition (PECVD, LPCVD, etc.), etc.

On completion of this assembly step, an assembly comprising the two associated substrates is available, with the flat face 6 of the support substrate 7 adhering to the flat face 4 of the donor substrate 1.

The assembly is then treated in order to detach the first layer 3 of ferroelectric material from the donor substrate 1, for example, by cleavage at the weakened plane 2.

This detachment step thus can involve applying a heat treatment to the assembly in a temperature range on the order of 80° C. to 300° C. in order to allow the first layer 3 to be transferred to the support substrate 7. As an alternative to or in addition to the heat treatment, this step can include applying a blade or a jet of gaseous or liquid fluid to the weakened plane 2.

Following this detachment step, the structure 9 shown in FIG. 1D is obtained. This structure 9 comprises the first layer 3 of single-crystal ferroelectric material comprising a first free face 8 and a second face 4 arranged on the support substrate 7.

FIGS. 2A to 2F show a second embodiment leading to the provision of this same structure 9. This second method is particularly suitable for producing a heterogeneous structure 9, in which the first layer 3 has a thermal expansion coefficient (in the main plane defining this layer) that is very different to that of the support 7, for example, having a difference of more than 10% (at ambient temperature).

This second embodiment mainly differs from the first embodiment in terms of the nature of the donor substrate 1. For the sake of conciseness, therefore, only the elements of this second embodiment that differ from the first embodiment are described herein, all the other features of the first embodiment therefore can be provided.

With reference to FIG. 2A, the donor substrate 1 in this case is made up of a thick layer 1a of ferroelectric material with the same properties as those described for the solid block of ferroelectric materials in relation to the first embodiment, and a handling substrate 1b.

The handling substrate 1b is advantageously made up of a material (or a plurality of materials) conferring a thermal expansion coefficient thereto that is close to that of the support substrate 7. The term “close” means that the difference between the thermal expansion coefficient of the handling substrate 1b and that of the support is less, as an absolute value, than the difference between the thermal expansion of the solid block of ferroelectric material and that of the support substrate 7.

Preferably, the handling substrate 1b and the support substrate have an identical thermal expansion coefficient. During the assembly of the donor substrate 1 and of the support 7, an assembly is formed that is capable of withstanding a heat treatment at a relatively high temperature. For the sake of ease of implementation, this can be obtained by selecting the handling substrate 1b so that it is made up of the same material as that of the support substrate 7.

In order to form the donor substrate 1 of this embodiment, a solid block of ferroelectric material is assembled with the handling substrate 1b beforehand, for example, by way of a molecular adhesion bonding technique, as described above, or using an adhesive layer. Next, the layer 1a of ferroelectric material is formed by thinning, for example, by grinding and/or chemical-mechanical polishing and/or etching. Before assembly, the formation of an adhesion layer (for example, by silicon oxide and/or silicon nitride deposition of an adhesive layer, for example, a polymer) on one and/or the other of the faces that have been brought into contact may have been contemplated. Assembly can comprise applying a low-temperature heat treatment (ranging, for example, between 5° and 300° C., typically 100° C.) allowing the bonding energy to be sufficiently enhanced to allow the following thinning step.

The handling substrate 1b is selected so as to have a thickness that is substantially equivalent to that of the support substrate 7. The thinning step is conducted so that the thickness of the thick layer 1a is low enough for the stresses generated during the heat treatments applied throughout the remainder of the method to be of reduced intensity. At the same time, this thickness is high enough to be able to remove the first layer 3, or a plurality of such layers, therefrom. This thickness can range, for example, between 5 and 400 microns.

The following steps of the method of this second embodiment are equivalent to those of the steps described in the first embodiment. Light species are implanted within the thick layer 1a in order to generate a weakened plane 2 that demarcates the separation of the thin layer 3 from the rest 5 of the donor substrate 1, as shown in FIG. 2B. This step is followed by a step of assembling the donor substrate 1 on the support substrate 7, as shown in FIG. 2C. Next, the first layer 3 is detached from a remainder 5 of the substrate 1 in order to obtain the structure 9 shown in FIG. 2D.

This embodiment is advantageous in that the assembly formed by the donor substrate 1 and the support 7 can be exposed to a temperature that is much higher than that applied within the context of the first embodiment, without risking the uncontrolled fracturing of one of the substrates or the delamination of the donor substrate 1 from the thin layer 3. The balanced structure, in terms of the thermal expansion coefficient of this assembly, thus facilitates the step of detaching the first layer 3 by exposing the assembly to a relatively high temperature, for example, ranging between 100° C. and 500° C.

Irrespective of the selected embodiment, and as specified in the introduction of this disclosure, steps of finishing the first layer 3 are subsequently necessary in order to improve its crystal and surface quality, and to provide a thin layer 3′ with a thickness that matches, or is close to, a target thickness. These finishing steps, which are schematically shown in FIG. 1E and FIG. 2E, are notably intended to eliminate a hard and rough surface layer resulting from the cleavage and detachment of the thin layer 3 from the rest of the donor substrate.

As disclosed in document WO 2020/200986, a heat treatment step is initially applied to the first removed layer 3. This heat treatment allows any crystalline defects present in this layer 3 to be rectified, and even allows the roughness of its free face 8 to be reduced. Furthermore, it helps to consolidate its adhesion to the support 7. The heat treatment brings the structure to a temperature ranging between 300° C. and the Curie temperature of the ferroelectric material for a duration ranging between 30 minutes and 10 hours. This heat treatment is preferably carried out by exposing the free face of the first layer 3 to an oxidizing or neutral gaseous atmosphere, i.e., without covering this face of the thin layer with a protective layer.

For the avoidance of doubt, it should be noted that the finishing heat treatment step is quite distinct from the fracturing heat treatment applied to the assembled structure. It is notably carried out in equipment different from that used to apply the fracturing heat treatment.

A method according to the present disclosure also includes, after the finishing heat treatment, a step of thinning the first thin layer. This step is notably aimed at eliminating the multi-domain surface portion of the first layer 3, with this portion having been created during the previous heat treatment step. It also aims to provide a thin single-domain layer 3′, the thickness of which corresponds to a target thickness, as previously stated. This thinning can generally correspond to polishing of the first free face 8 of the thin layer 3, for example, by way of mechanical or chemical-mechanical thinning techniques. It can also involve thinning carried out by ion etching, for example, by reactive ion etching.

In all cases, this thinning results in the elimination of at least the thickness of the multi-domain portion of the first layer 3, with this thickness typically being on the order of at least 150 nm, which leads to the disadvantages described in the introduction to this disclosure. FIGS. 1F and 2F show the structure 9 obtained on completion of these treatments, with a thin single-domain layer 3′ being arranged on the support 7.

In order to characterize the thickness of the multi-domain surface portion, a sample of this layer is usually inspected by way of transmission electron microscopy. This inspection technique allows the multi-domain surface portion and the underlying single-domain portion to be visualized and distinguished in the cross-section of the sample. However, the extent of this view remains limited to inspection fields of a few hundred microns, which does not fully represent the quality of the first layer 3 over its entire extent. It is also a long and complex technique to deploy.

In order to overcome this analysis problem, a faster characterization technique has been developed that enables the thickness of the multi-domain portion to be assessed more broadly.

This technique comprises a first step involving removing a given thickness of the first layer 3 (for example, 125 nm) by chemical-mechanical polishing. Following this first step, the topography of the revealed face is measured: a high topography indicates the multi-domain quality of the material whose face is exposed and, conversely, a low topography indicates the single-domain quality of the material whose face is revealed. The topography measurement can be carried out by atomic force measurement (AFM) on measurement fields of 5 micrometers by 5 micrometers. Within the context of this disclosure, “high topography” is understood to mean a surface with a peak-to-valley roughness of 10 nm or more, and, conversely, “low topography” is understood to mean a surface with a peak-to-valley roughness of less than 10 nm.

The speed of the chemical or physico-chemical etching of the thin layer 3 occurring during the polishing step is rendered variable by the nature of the polarity of the removed piezoelectric material: the Z− side of this layer is etched much faster than the Z+ side. Consequently, polishing a single-domain layer will have a much lower surface topography than polishing a multi-domain layer.

Furthermore, according to the proposed characterization technique, by assessing the topography of the exposed face of the thin layer after it has been thinned by a given thickness, it is possible to very simply determine whether the multi-domain layer extended to a depth greater than the given thickness (revealed by a high topography) or whether it extended to a thickness less than the given thickness (revealed by a low topography). This somewhat rough characterization of the multi-domain thickness nevertheless allows an overall assessment to be provided of this thickness by repeating the topography measurement on a plurality of locations sampling the entire extent of this layer.

Using this global characterization technique, which is quick to implement, and by selecting a specific thickness of 125 nm, it has been realized that the method for preparing a thin layer 3 of a ferroelectric material as described above (according to two different embodiments) leads to the formation, after the step of heat treating the transferred thin layer 3 and before the thinning step, of a multi-domain surface layer that is at least 125 nm.

In the search for a solution for reducing the thickness of this multi-domain surface portion, it was surprisingly discovered that introducing a sufficient hydrogen dose into a surface thickness of the first layer 3, before applying the heat treatment step to this layer 3, tended to reduce the thickness of the multi-domain surface portion that is revealed during this heat treatment.

This discovery results from experiments that were conducted and that involved applying, immediately after the step of fracturing a first layer of lithium tantalate, interlayer treatment to the free face 8 of the first thin layer. After this interlayer treatment step, the heat treatment was applied that led to the development of the multi-domain surface portion, which was characterized using the technique described above, by reducing the thickness of the first 125 nm layer by polishing and then measuring its topography.

These experiments included the following list of interlayer treatments of the first layer 3:
Cleaning 1: cleaning the free face 8 of the first thin layer by brushing and dispensing deionized water at ambient temperature. Characterization of the layer after heat treatment revealed a thickness of more than 125 nm for the multi-domain surface portion.
Cleaning 2: cleaning the free face of the thin layer 3 by successive immersion in baths of deionized water, SC1 and SC2, all at ambient temperature. Characterization of the layer after heat treatment revealed a thickness of more than 125 nm for the multi-domain surface portion.
Cleaning 3: cleaning the free face by successive immersion in baths of deionized water, SC1 and SC2, with the SC1 solution being heated to 70° C. this time. Characterization of the layer after heat treatment revealed a thickness of less than 125 nm for the multi-domain surface portion.

In an attempt to understand the reason for this phenomenon, SIMS (Secondary Ion Mass Spectrometry) measurements of the first layer 3 were carried out to determine the hydrogen concentration profile according to the depth of the first layer. FIG. 3 thus shows the hydrogen concentration profile of the first layer 3 directly after fracturing (without applying the cleaning—NET0), after applying the cleaning 1 (NET1) and after applying the cleaning 3 (NET3). A hydrogen-rich surface zone can be seen that is on the order of 200 nm thick. Applying the cleaning 3 (which limits the thickness of the multi-domain surface portion) produces a hydrogen concentration in the surface zone on the order of 3.0E21 at/cm³, whereas it does not exceed a concentration of 1.0E21 at/cm³ in the other cases.

When these hydrogen concentration data are processed, it can be seen that the cleaning 1 introduces a hydrogen dose of 1.4E16 at/cm² into the first layer 3, yet without allowing the thickness of the surface multi-domain portion to drop below 125 nm. For its part, the cleaning 3 introduces a hydrogen dose of 4.3E16 at/cm² and reduces the thickness of the multi-domain portion below 125 nm.

These preliminary results tending to link the thickness of the surface multi-domain portion to the concentration of hydrogen in the first layer 3 were confirmed by other experimental measurements.

According to one of these measurements, applying a treatment to the free face of the thin layer 3 involved applying a sequence of five cleaning steps using a deionized water solution, with the cleaning steps being separated from each other by a waiting time of 24 hours or more. The solution was at ambient temperature. This treatment resulted in a multi-domain thickness of less than 125 nm, from the third cleaning step in the sequence.

The effect of these cleaning steps is to eliminate a thin surface layer of Li₂CO₃ on the thin layer 3 obtained directly after the fracturing step. Its formation seems to be favored by the particular conditions in which the fracturing step occurs. The presence of light species, namely hydrogen and/or helium, and the moderate temperature at which the fracturing occurs seem to render the lithium in the thin layer 3 particularly mobile and the surface of this layer 3 particularly reactive. This surface thickness of Li₂CO₃ is on the order of a nanometer or more thick. It is stable over time, i.e., it does not change in consistency or thickness when the thin layer 3 is kept exposed to the atmosphere. However, this surface layer of Li₂CO₃ is relatively fragile, and it has been observed that it could be eliminated by simple wet cleaning. It has also been observed that the thin layer 3, cleaned and devoid of its surface thickness of Li₂CO₃, remained particularly reactive. By keeping the free face of the thin layer 3 exposed to the atmosphere for an extended period of time, amorphous dendrites, rich in lithium and hydrogen (and other species present in the atmosphere such as chlorine or fluorine) nucleate and develop again. Carrying out successive cleaning steps that are separated from each other by a sufficient duration tends to strip a surface thickness of the thin layer 3 of its lithium (which migrates and accumulates on the surface) and, at the same time, tends to introduce hydrogen elements as a replacement. When a sufficient hydrogen dose has been introduced into the thin layer 3, the heat treatment applied to this layer leads to the formation of a multi-domain thickness of less than 125 nm, which confirms the hypothesis that increasing the hydrogen concentration in a surface thickness of the thin layer 3 tends to reduce the thickness of the surface multi-domain portion induced by the heat treatment of the finishing sequence of this layer.

As a final experimental measure, a 30 nm thickness of hydrogen-rich silicon oxide was formed on the thin layer 3 by PECVD deposition. The finishing sequence was then annealed, resulting in a significant hydrogen dose being injected into the thin layer 3 by diffusion. Characterization of this thin layer 3, after removing the silicon oxide layer, revealed that the multi-domain layer was less than 125 nm thick.

It was concluded from these experiments that treatment of the free face of the first layer 3 that is aimed at forming a high hydrogen concentration in a surface thickness of this layer, for example, greater than 2.0E21 at/cm³ in a surface thickness of 100 nm or 200 nm, allowed the thickness of the surface multi-domain portion to be significantly reduced.

Advantageously, treatment of the free face results in a hydrogen dose being introduced into the first layer 3 that is greater than or equal to 2.0E16 at/cm².

Under these conditions, the thickness of the surface multi-domain portion revealed by the heat treatment of the finishing sequence is less than 125 nm.

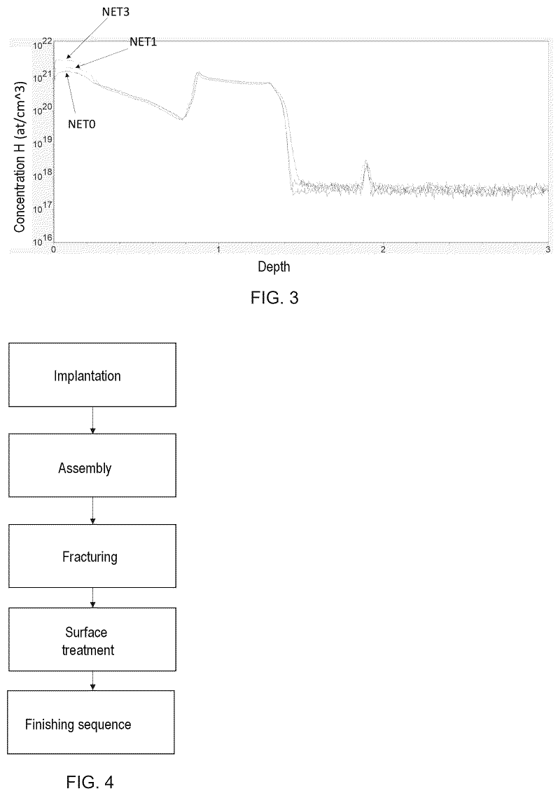

Therefore, the invention benefits from these results in order to propose a method for preparing a thin single-domain layer 3′. This method is schematically shown in FIG. 4. It uses all the steps disclosed in relation to the description of FIGS. 1A to 1E and 2A to 2E. In particular, this method comprises:
a step of implanting “light” species in a first face 4 of a ferroelectric donor substrate 1 to form a weakened plane 2 and to define a first layer 3 between the weakened plane 2 and the first face 4 of the donor substrate 1;
a step of assembling the first face 4 of the donor substrate 1 on a support 7 to form an intermediate assembly;
a step of fracturing the intermediate assembly, comprising a first heat treatment, with this step leading to the fracturing of the donor substrate 1 at the weakened plane 2 and to the formation of a free face 8 of the first layer 3;
a sequence for finishing the first layer 3 comprising an annealing step including a second heat treatment and, after the annealing step, a step of thinning the first layer 3 to form the thin single-domain layer 3′.

According to the present disclosure, the preparation method comprises, between the fracturing step and the finishing sequence, applying a treatment to the free face 8 of the first layer in order to produce a hydrogen concentration that is greater than 2.0E21 at/cm³ in a surface thickness of the first layer 3.

This hydrogen-rich surface thickness of the first layer can be at least 100 nm thick from the free face 8 of this first layer. Advantageously, it is at least 200 nm thick.

The hydrogen concentration can be obtained by selecting the treatment of the free face so that this treatment introduces a hydrogen dose into the first layer 3 that is greater than or equal to 2.0E16 at/cm².

According to a first approach, treating the free face 8 comprises immersing the first layer 3 in a first solution that is at a temperature higher than ambient temperature, for example, higher than 50° C., preferably higher than or equal to 65° C. This first solution can be or can include SC1. The treatment of the first layer can notably correspond to RCA type cleaning, involving, as is well known per se, a sequence formed by successive immersion of the structure comprising the first layer 3 in baths of deionized water, SC1 and SC2. When the treatment of the free face 8 is implemented by such RCA type cleaning, the temperature of the bath of SC1 in which the structure is immersed is higher than the ambient temperature.

According to another approach, the treatment of the free face 8 comprises a sequence of cleaning steps using a second solution, with the cleaning steps being separated from one another by a waiting time of 24 hours or more. The cleaning steps can correspond to brushing the free face 8 and, at the same time, to dispensing deionized water onto the free face 8 of the first layer 3, with the deionized water then forming the second solution used during the cleaning steps. This second solution can be at ambient temperature or can be brought to a temperature above ambient temperature.

Advantageously, the sequence of cleaning steps comprises at least three cleaning steps, preferably at least five cleaning steps.

According to yet another approach, treating the free face 8 comprises depositing a hydrogen-rich covering layer onto the free face 8, for example, with a hydrogen concentration of more than 1.0E20 at/cm³. The covering layer can notably comprise silicon dioxide, silicon nitride or silicon oxynitride formed, for example, by a chemical vapor deposition technique at sub-atmospheric pressure. Irrespective of the nature of the covering layer, it can be 20 nm or more thick to contain a sufficient amount of hydrogen.

By introducing hydrogen into the first layer 3 before applying the finishing sequence to this layer, it is possible to reduce the thickness of the multi-domain surface portion revealed by this sequence. In particular, it is possible to limit this thickness to less than 125 nm.

Of course, the present disclosure is not limited to the described embodiments, and alternative embodiments can be used without departing from the scope of the invention as defined by the claims.

In particular, treatment of the free face 8 can be applied between the fracturing step and the finishing sequence, combining the three illustrated approaches and according to any possible combination.

The treatment of the free face of the removed layer 3 can also correspond to any other treatment of this face leading to the introduction of a sufficient hydrogen dose into this layer.

1. A method of preparing a thin single-domain layer of ferroelectric material, the method comprising:
implanting light species in a first face of a ferroelectric donor substrate to form a weakened plane and to define a first layer between the weakened plane and the first face of the donor substrate;
assembling the first face of the donor substrate on a support to form an intermediate assembly;
fracturing the intermediate assembly using a first heat treatment leading to the fracturing of the donor substrate at the weakened plane and to the formation of a free face of the first layer;
finishing the first layer using an annealing including a second heat treatment and, after the annealing, thinning the first layer to form the thin single-domain layer; and
wherein the method further comprises, between the fracturing of the intermediate assembly and the finishing of the first layer, applying a treatment to the free face to produce a hydrogen concentration that is greater than 2.0E21 at/cm³ in a surface thickness of the first layer.

2. The method of claim 1, wherein the surface thickness, in which the hydrogen concentration is greater than 2.0E21 at/cm³, is greater than or equal to 100 nm.

3. The method of claim 2, wherein the surface thickness is greater than or equal to 200 nm.

4. The method of claim 1, wherein the treatment of the free face introduces a hydrogen dose into the first layer that is greater than or equal to 2.0E16 at/cm².

5. The method of claim 1, wherein the treatment of the free face comprises immersing the first layer in a first solution having a temperature higher than ambient temperature.

6. The method of claim 5, wherein the first solution comprises SC1 and/or SC2.

7. The method of claim 5, wherein the temperature of the first solution is greater than 50° C., preferably greater than 65° C.

8. The method of claim 1, wherein the treatment of the free face comprises a sequence of cleaning steps using a second solution, with the cleaning steps of the sequence being separated from one another by a waiting time that is 24 hours or more.

9. The method of claim 8, wherein the second solution comprises deionized water, and the sequence of cleaning steps includes at least three cleaning steps each comprising simultaneously brushing and dispensing deionized water onto the free face of the first layer.

10. The method of claim 8, wherein the second solution is at ambient temperature.

11. The method of claim 8, wherein the sequence of cleaning steps comprises at least five cleaning steps.

12. The method of claim 1, wherein the treatment of the free face comprises depositing a covering layer onto the free face with a hydrogen concentration that is greater than 1.0E20 at/cm³.

13. The method of claim 12, wherein the covering layer comprises silicon dioxide, silicon nitride or silicon oxynitride.

14. The method of claim 13, wherein the covering layer has a thickness of 20 nm or more.

15. The method of claim 1, wherein the thin single-domain layer comprises a single-crystal piezoelectric material.

16. The method of claim 15, wherein the thin single-domain layer comprises lithium niobate.

17. The method of claim 1, wherein the assembling comprises forming a dielectric interlayer on the first face of the donor substrate and/or on the support.

18. The method of claim 7, wherein the temperature of the first solution is greater than 65° C.

19. The method of claim 15, wherein the thin single-domain layer comprises lithium tantalate.
